(19) United States
(12) Patent Application Publication
(10) Pub. No.: US 2015/0340557 A1
(43) Pub. Date: Nov. 26, 2015

(54) SHAPED LED FOR ENHANCED LIGHT EXTRACTION EFFICIENCY

(71) Applicant: Koninklijke Philips N.V., Eindhoven (NL)

(72) Inventors: Stéphane TURCOTTE, Eindhoven (NL); Songnan WU, Eindhoven (NL)

(21) Appl. No.: 14/653,005

(22) PCT Filed: Dec. 17, 2013
(86) PCT No.: PCT/IB2013/061038

§ 371 Date: Jun. 17, 2015

Related U.S. Application Data
(60) Provisional application No. 61/749,941, filed on Jan. 8, 2013.

(51) Int. Cl. H01L 33/20; H01L 33/46; H01L 33/24; H01L 33/00

(52) U.S. Cl. CPC H01L 33/20; H01L 33/0095; H01L 33/46; H01L 33/24; H01L 2933/0025

(57) ABSTRACT

The shape of a light emitting element 400;500) is designed to increase the amount of light that is able to escape from the surfaces of the light emitting element (400;500). The indices of refraction of the light emitting element (400;500) and the surrounding environment define an escape zone through which light may escape through a surface of the light emitting element (400;500). Light traveling outside the escape zone is totally internally reflected (TIR) at the surface. By increasing the number of surfaces on the light emitting element (400;500), the number of escape zones (410a-f,411a-f, 510a-h,511a-h) may be increased, with a corresponding increase in the likelihood of light escaping the surfaces. A light emitting element (400;500) comprising a polygonal surface area with more than four sides (402a-f;502a-h) exhibits a higher light extraction efficiency, and also allows a more uniform current injection, and experiences reduced mechanical stress, compared to one comprising a rectangular surface area.

### FIELD OF THE INVENTION

This invention relates to the field of light emitting devices, and in particular to light emitting devices that are shaped to increase the efficiency of extraction of light from the surfaces of the device.

### BACKGROUND OF THE INVENTION

The increased use of solid-state light emitting devices (LEDs) for lighting applications has created a highly competitive market in which cost and lighting efficiency are predominant factors. Techniques that improve the light output efficiency of the devices and/or the lighting assembly are desirable to distinguish the devices from the competition and increase market share.

A common technique for improving light output efficiency is to enclose the light emitting device 110 in a reflective structure 120, typically parabolic, that directs the emitted light in a desired direction, as illustrated in FIG. 1A. Such a reflector 120 may be used, for example, to direct the light from a flash element in a camera or other portable device, such as a cell phone. To maximize the advantages provided by such a reflector 120, most of the emitted light should be directed toward the reflective surface, so that it is redirected toward the desired direction 130, as illustrated by light rays 140. Light that does not strike the reflective surface 120 may travel in an unwanted direction, as illustrated by the light rays 150. Accordingly, conventional light emitting devices 110 that use a parabolic reflector are commonly configured to emit light in a lateral direction, relative to the “upper” light emitting surface 114 of the light emitting element 112, toward the reflective surface 120. A concentric side-reflecting lens 118, such as illustrated in FIG. 1B, is commonly used to provide redirection of the light emitted from the upper surface 114 of the light emitting element 112.

In like manner, semiconductor light emitting elements are commonly used as backlights for illuminating display screens. Commonly, side-emitting structures are situated adjacent to or within a light guide that is situated below the display panel. The side-emitting light illuminates the light guide, which subsequently illuminates the display panel.

### SUMMARY OF THE INVENTION

It would be advantageous to increase the light output efficiency of a light emitting device. It would also be advantageous to improve the uniformity of the light output and/or to improve the reliability of the light emitting device.

To better address one or more of these concerns, in an embodiment of this invention, the shape of the light emitting element is designed to increase the amount of light that escapes from the surfaces of the light emitting element. The indices of refraction of the light emitting element and the surrounding environment define an escape zone through which light may escape through a surface of the light emitting element. Light traveling outside the escape zone is totally internally reflected (TIR) at the surface. By increasing the number of surfaces on the light emitting element, the number of escape zones may be increased, with a corresponding increase in the likelihood of light escaping the surface. A polygonal surface with more than four sides also provides for more uniform current injection, and reduced mechanical stress, compared to a rectangular surface.

A light emitting element includes a cross-section-view profile and a top-view profile, and in embodiments of this invention, at least one of these profiles is substantially different from rectangular. In example embodiments, the profiles comprise polygons of at least five sides or a polyhedron of at least 7 planes. One or more of the surfaces outlined in the profile may be reflective, which will redirect light toward a desired direction. One or more of the surfaces (planes) outlined in the profile may be used for electrical contact or current injection purposes. The light emitting element may be situated on a substrate, and the top-view profile of the substrate may correspond to the top-view profile of the light emitting element, or it may differ. The substrate may include features that facilitate the creation of light emitting elements with non-rectangular profiles. The LED may be shaped laterally (2D) by its sides, where a top view would seem of polygonal nature, or can be shaped in the three directions (3D) in the shape of a polyhedron.

### BRIEF DESCRIPTION OF THE DRAWINGS

The invention is explained in further detail, and by way of example, with reference to the accompanying drawings wherein:

FIG. 1A illustrates an example prior art light emitting device with parabolic reflector, and

FIG. 1B illustrates an example prior art side emitting device for use with such a reflector.

FIGS. 2A and 2B illustrate side and top views of a rectangular light emitting element.

FIGS. 3A and 3B illustrate example escape zones of a rectangular light emitting element.

FIGS. 4A and 4B illustrate example escape zones of a hexagonal light emitting element.

FIGS. 5A and 5B illustrate example escape zones of from an octagonal light emitting element.

FIGS. 6A-6D illustrate example alternative shapes for non-rectangular light emitting elements.

FIGS. 7A-7E illustrate example wafers comprising non-rectangular light emitting elements.

FIGS. 8A-8B illustrate example light emitting elements with non-rectangular cross-section profiles.

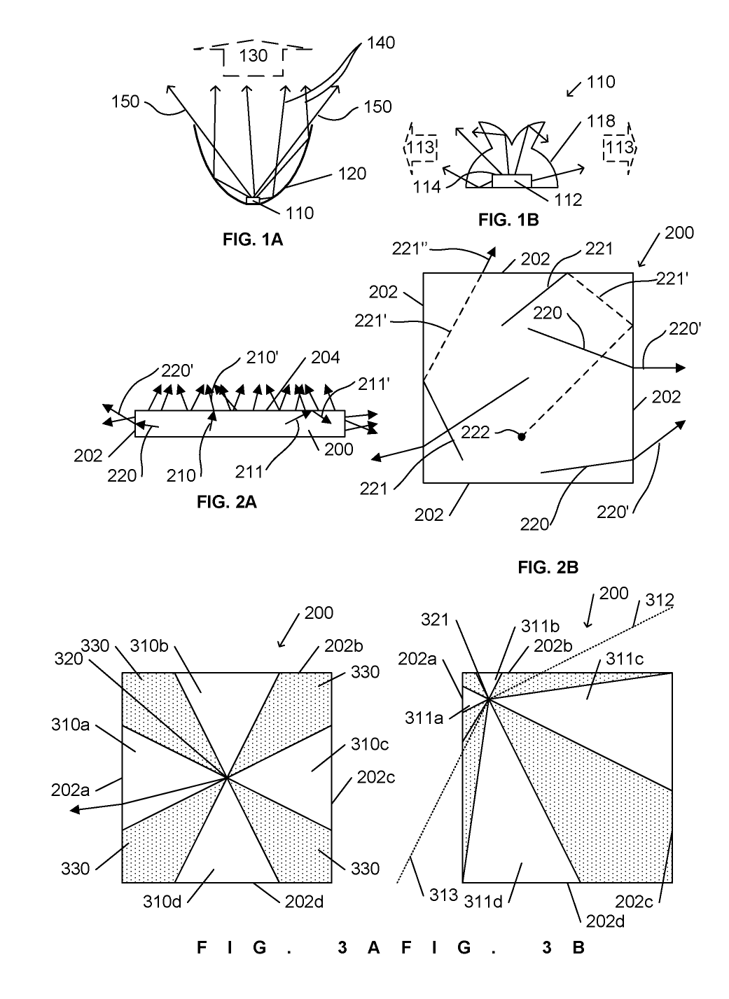

Throughout the drawings, the same reference numerals indicate similar or corresponding features or functions. The drawings are included for illustrative purposes and are not intended to limit the scope of the invention.

### DETAILED DESCRIPTION

In the following description, for purposes of explanation rather than limitation, specific details are set forth such as the particular architecture, interfaces, techniques, etc., in order to provide a thorough understanding of the concepts of the invention. However, it will be apparent to those skilled in the art that the present invention may be practiced in other embodiments, which depart from these specific details. In like manner, the text of this description is directed to the example embodiments as illustrated in the Figures, and is not intended to limit the claimed invention beyond the limits expressly included in the claims. For purposes of simplicity and clarity, detailed descriptions of well-known devices, circuits, and methods are omitted so as not to obscure the description of the present invention with unnecessary detail.

In example embodiments of this invention, the shape of the light emitting element is controlled to reduce the likelihood that light emitted from points within the device will strike a surface at greater than the critical angle, relative to a normal to the surface. The critical angle is determined by the indices of refraction n1 and n2 of the material on either side of the surface, and is equal to:

arcsin(n2/n1), (Equation 1)

for light traveling from the medium having an index of refraction n1 into a medium having an index of refraction of n2. Light that strikes the surface at greater than the critical angle will be totally internally reflected, and will not escape through the surface. The term “escape zone” is used to define the range of angles within which light will escape through the surface.

In the ideal case, all of the light from a point source at the center of a sphere that strikes the surface of the sphere will escape through the surface, because the light that is emitted from the center of the element will strike the surface of the sphere at an angle that is normal to the surface. Point sources, however are not currently feasible, and given that the light source will consume some space within the sphere, not all of the light will be emitted from the exact center of the sphere.

Light that is generated from points that are off center may strike the spherical surface at angles that are not normal to the surface, but the likelihood of the light striking the spherical surface at angles greater than the critical angle is substantially less than the likelihood of light striking a planar surface at angles greater than the critical angle. This is due to the fact that each point on the spherical surface has an escape zone relative to a tangent to the surface; and, relative to each point within the sphere, these escape zones will overlap.

Similarly, the escape zones from the sides of a cylindrical surface will also overlap, providing for a high light extraction efficiency for light emitted in the direction of the curved outer surface.

Despite the efficiencies that may be gained by the use of spherical or cylindrical surfaces surrounding the light source, the costs associated with forming light emitting elements in the shape of spheres or cylinders precludes their use for commercial production of light emitting elements. The forming of such shapes from a wafer of multiple light emitting elements would generally require milling, laser-cutting, or mechanical sawing of each light emitting element, with significant waste of the materials between each light emitting element produced by such processes.

Although spherical or cylindrical light emitting devices may not currently be feasible, the principles of this paradigm can be applied to use other shapes that improve the likelihood of light escaping directly from points within a light emitting region. In example embodiments of this invention, for example, multi-sided shapes are used to increase the number of escape zones, thereby increasing the likelihood that the light generated from points within the light emitting element will be within an escape zone. Preferably, the shapes are formed using multiple planar surfaces, thereby avoiding the need to shape curved surfaces; and, if the planar surfaces of adjacent light emitting elements are arranged on the wafer in alignment, a single slicing operation may be used to provide these aligned surfaces. Additionally, if the planar surfaces abut each other, less material is wasted in the formation of the individualized (‘singulated’) light emitting elements. For example, a regular hexagonal tessellation provides a pattern of hexagons that is devoid of space between the hexagons. Although such a design does not provide for a simple cutting/slicing pattern, with the advances in techniques such as laser slicing, the cost of effecting hexagonal slices may be offset by the elimination of waste that needs to be allowed for and disposed of.

FIGS. 2A and 2B illustrate side and top views of a rectangular light emitting element 200. As illustrated in FIG. 2A, the majority of light from the light emitting element 200 is emitted from the upper surface 204 of the light emitting element. Light 210 is generated within the interior of the light emitting element 200, and strikes the surface 204. If the light 210 is within the escape zone of the light emitting element 200 relative to the surface 204, it is able to escape through the surface as emitted light 210′; if the light 211 is not within the escape zone, the light 211 will be totally internally reflected (TIR) as light 211′.

In addition to the light 210, 211 that strikes the upper surface 204, some light 220, 221 will strike the sides 202, or edges, of the light emitting element 200, as further illustrated in FIGS. 2B. If the light 220 is within the escape zone relative to the side 202, it will be emitted as light 220′; if the light 221 is not within the escape zone, it will be totally internally reflected as light 221′.

The light 211, 221 that is reflected from the surfaces 204, 202 may eventually strike another surface within the escape zone of that surface and will be emitted from that surface, as illustrated as 221″ in FIG. 2B. Some of the reflected light, however, may be absorbed within the light emitting element 200 before it is able to escape; it may also continue to be internally reflected, further increasing the likelihood that this reflected light will be absorbed within the light emitting element 200 and converted to heat energy, as illustrated by the terminated reflected light at 222 in FIG. 2B.

As noted above, the likelihood of light being emitted through a surface is dependent upon the escape zone associated with the surface. This escape zone is determined by the indices of refraction on either side of the surface. If the light strikes the surface within the ‘critical angle’, the light will travel through the surface; if not, it will be totally internally reflected. Relative to the surface, a projection of the extent of the critical angle about a normal to the surface from a point within the structure defines a zone for light generated from that point escaping through the surface.

The index of refraction of an AlInGaP active region is about 3.5, and the index of refraction of a silicone encapsulant is about 1.4. Accordingly, using Equation 1, above, the critical angle for light generated within such an active region escaping through a surface and into the silicone encapsulant is about 23.6 degrees. Thus, the escape zone for light generated from a point within the active region is a cone whose cross-section subtends the angle 2*23.6 degrees (+/−23.6 degrees relative to a normal to the surface), which amounts to a solid angle of about 0.53 steradians. The escape zone for light into air from AlInGaP is about +/−17.5 degrees, which amounts to about 0.3 steradians.

Although escape zones are defined by solid angles, this disclosure is presented using a two dimension model, for ease of presentation and understanding. One of skill in the art will recognize that the conclusions drawn from the following analysis of two dimensional optical models are the same as the ones that would be drawn from a more complex analysis using a three dimensional model.

In the subsequent presentation, for ease of understanding, the example critical angle is about 24 degrees, corresponding to this example combination of an AlInGaP active region and a silicone encapsulant. One of skill in the art will recognize that the principles of this invention are applicable to any particular combination of material and/or any particular value of the critical angle.

FIG. 3A illustrates a top view of example escape zones 310a, 310b, 310c, 310d (collectively, cones 310) from a point 320 at the center of the light emitting element 200 relative to each of the sides 202a, 202b, 203c, and 203d (collectively, sides 202), respectively, using the above example of a critical angle of about 24 degrees. Any light that is emitted from the center point 320 at an angle within the escape zones 310 will escape through the surface 202; light emitted from the center point 320 at angles outside the escape zones 310 will be totally internally reflected. The regions 330 outside the illustrated escape zones 310 are shaded in FIG. 3A.

Light that may be generated from the center point 320 may be emitted at any angle. Using a two dimensional model, the emitted light may be emitted over a range of 0-360 degrees toward the sides 202. Of this entire 360 degree range, the light will either be within an escape zone 310, or a TIR region 330. Assuming a critical angle of 24 degrees, the escape zones amount to 192 degrees (4*48 degrees), or just over half (192/360) the range of emitted light. Thus, almost half (178/360) of the light emitted from the center 320 of the active region toward the sides 202 will be internally reflected when it strikes the sides 202 of the light emitting element 200. As noted above, internally reflected light travels further through the active region before it may escape, thereby increasing the likelihood that it will be absorbed before being able to escape.

The escape zones for any particular point in the active region will depend upon the relationship between that particular point and each of the sides 202 of the light emitting element 200. The amount of light that is able to escape from points away from the center 320 will generally be even less than this estimated 53% (192/360) from the center point 320 of the light emitting element 200, as illustrated in FIG. 3B.

FIG. 3B illustrates example escape zones 311a, 311b, 311c, and 311d of an example point 321 within the light emitting element 200 relative to the sides 202a, 202b, 202c, and 202d. As illustrated in this example two dimensional model, escape zones 311a and 311b will allow light within the full range of 48 degrees each to escape through the surfaces 202a and 202b. However, because the point 321 is offset significantly from center, the span of the escape zones 311c and 311d are truncated, because the full 48 degree span, as illustrated by the dotted lines 312, 313 extends beyond the surfaces 202c and 202d. Thus, the escape zones 311c and 311d provide less than the full escape range of 48 degrees. Accordingly, the amount of light generated at point 321 that will escape through the sides 202c and 202d is reduced, and the amount of light that will be totally internally reflected at these sides 202c and 202d is increased. In this example, the escape zones 311 amount to about 150 degrees, and the proportion of light from point 321 toward the surfaces 202a-202d that is directly emitted is reduced to about 42% (150/360).

The total proportion of light that can be expected to directly exit the surfaces 202 from the light emitting element 200 will be the integral of the proportion of light that can be expected to exit the surfaces 202 from each point within the light emitting element 200. As the example of FIG. 3B illustrates, however, this integral will generally be less than the proportion of light that can be expected to exit the surfaces 202 from a point in the center of the light emitting element. Thus the proportion determined based on light emitted from the center of the light emitting element can generally be considered a maximum proportion of light that can be expected to directly exit the surfaces 202, without being totally internally reflected.

The light extraction efficiency (the amount of light that is emitted v. the amount of light generated) is commonly increased by increasing the size of the escape zones, typically by reducing the differences in indices of refraction. However, the cost and complexity of refractive index matching limits the amount of improvement that is feasible and/or practical.

FIGS. 4A and 4B illustrate example escape zones in a hexagonal light emitting element 400. As in the prior example of a rectangular light emitting element having an AlInGaP active region surrounded by a silicone encapsulant, the width of each example escape zone is about 48 degrees.

The escape zones 410a-f of FIG. 4A are illustrated for light that is generated at the center 420 of the light emitting element 400. Because there are six escape zones, the proportion of light from the center 420 toward the sidewalls 402a-f that will directly escape through the sidewalls 402a-f of the hexagonal light emitting element 400 is about 80% (6*48/360), as compared to 53% (4*48/360) in the rectangular light emitting element 200 of FIG. 3A.

The escape zones 411a-f of FIG. 4B are illustrated for light that is generated at a point 421 that is substantially distant from the center 420. Although the proportion of the generated light that will be totally internally reflected (shaded TIR regions) from the sides 402a-f is greater than the example of FIG. 4A, it can be shown that the angles encompassed by these TIR regions amount to less than the angles encompassed by the TIR regions of FIG. 3B. In this example, the escape zones amount to about 180 degrees, as compared to about 160 degrees in FIG. 3B. [Not directly. In the example of FIG. 3B, the escape cones 311a and 311b amount to very little of the edge. However, assuming light is emitting in a random direction, these cones will amount to more than half the light that is able to directly escape the light emitting element 200.]

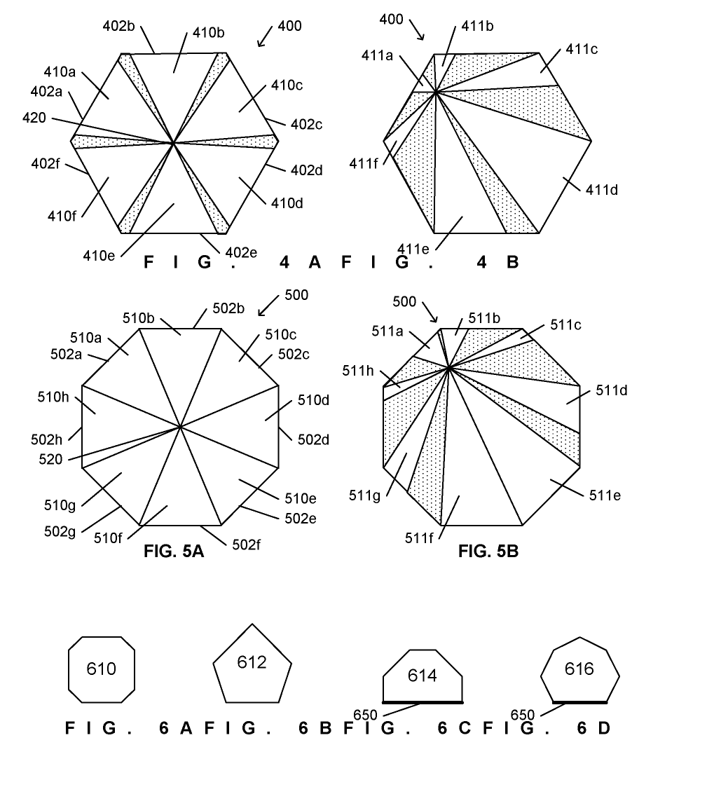

As the shape more closely approximates a circular perimeter, the light extraction efficiency will further increase. FIGS. 5A and 5B illustrate example escape zones in an octagonal light emitting element 500.

FIG. 5A illustrates the escape zones 510a-h from the center 520 of the light emitting element 500 relative to each surface 502a-h, using the same example AlInGaP active region surrounded by a silicone encapsulant. Because each escape zones encompasses 48 degrees, and each side 502a-h extends 45 degrees relative to the center 520, there is no direction from the center 520 toward the sidewalls 502a-h that is not within an escape zone 510a-h. Accordingly, all (8*45/360=100%) of the light that is generated at the center of the octagonal light emitting element 500 toward the sidewalls 502a-h will exit the light emitting element 500, as compared to 53% (4*48/360) in the rectangular light emitting element 200 of FIG. 3A, and 80% (6*48/360) in the hexagonal light emitting element 400 of FIG. 4A.

FIG. 5B illustrates the escape zones 511a-h from an off-center point 511 relative to the sidewalls 502a-h. As can be seen, the escape zones 511a-h of the octagonal light emitting element 500 encompass a larger area than the escape zones 411a-f of the hexagonal light emitting element 400 of FIG. 4B, and the escape zones 311a-d of the rectangular light emitting element 200 of FIG. 2B.

Further improvements in light extraction efficiency may be achieved by further increasing the number of sides of the light emitting element, and correspondingly, the number of escape zones.

As the shape of the light emitting element approaches a circular shape, other advantages will also be realized, compared to the rectangular shape.

Semiconductor light emitting elements rely on current injection through the semiconductor layers and into the light emitting region between these layers. To provide current injection across the entire area of the semiconductor layers and light emitting region, the contacts that provide current to the semiconductor layers are shaped to cover as much of the surface area of the semiconductor layer as possible.

A rectangular light emitting element will typically have rectangular contacts that connect to each of an N-type and a P-type semiconductor layer. However, a rectangular contact will exhibit non-uniform current injection and current crowding, which will cause a non-uniform light output pattern. Some of these adverse effects, such as current crowding, are more likely to occur at the corners of the contacts, and can become more pronounced as the angle formed at the corner of the contact gets narrower. Therefore, the corners of a rectangular die will be more susceptible to non-uniform current spreading and other electrical edge effects.

In a rectangle, the corners have an angle of 90 degrees. In a hexagon, the angle increases to 120 degrees, and in an octagon, the angle increases to 135 degrees. Accordingly, the adverse effects, such as non-uniform current injection, current crowding, and others will be substantially reduced as the number of sides of the light emitting element increases.

Additionally, a rectangular structure exhibits concentrated mechanical stress at the orthogonal corners, and mechanical failures are more likely to be produced at these corners. The corners on structures with more sides than a rectangular structure, on the other hand, will exhibit less mechanical stress, because the corners are blunter. By increasing the number of sides along the perimeter of a light emitting element, the interior angles are increased, reducing the mechanical stress that occurs at the vertices of the light emitting element.

Due to the significant increase in side-emission efficiency that can be expected, the use of many-sided polygons may allow for light emitting elements that emit solely, or primarily, through the sides. Such embodiments may allow, for example, full blanket sheets of contact deposition for the top and bottom contacts to the light emitting element, and allow for these contacts to be opaque, thereby extending the range of materials that may be used for the contacts, including reflective materials.

One of skill in the art will recognize that any of a variety of shapes may be employed to achieve a desired light output pattern from the sides of a light emitting element, and that theses shapes need not be regular polygons, nor even symmetric. FIGS. 6A-6D illustrate other example shapes 610, 612, 614, and 616. In FIGS. 6C and 6D, a reflective surface 650 is formed on one of the sides of the light emitting elements 614 and 616 to redirect light that strikes that surface, regardless of the angle of incidence, so as to produce an asymmetric distribution of light from the sides of the light emitting elements 614, 616. Such an asymmetric distribution may be advantageously used, for example, along the edges of a waveguide that provides backlighting to a display.

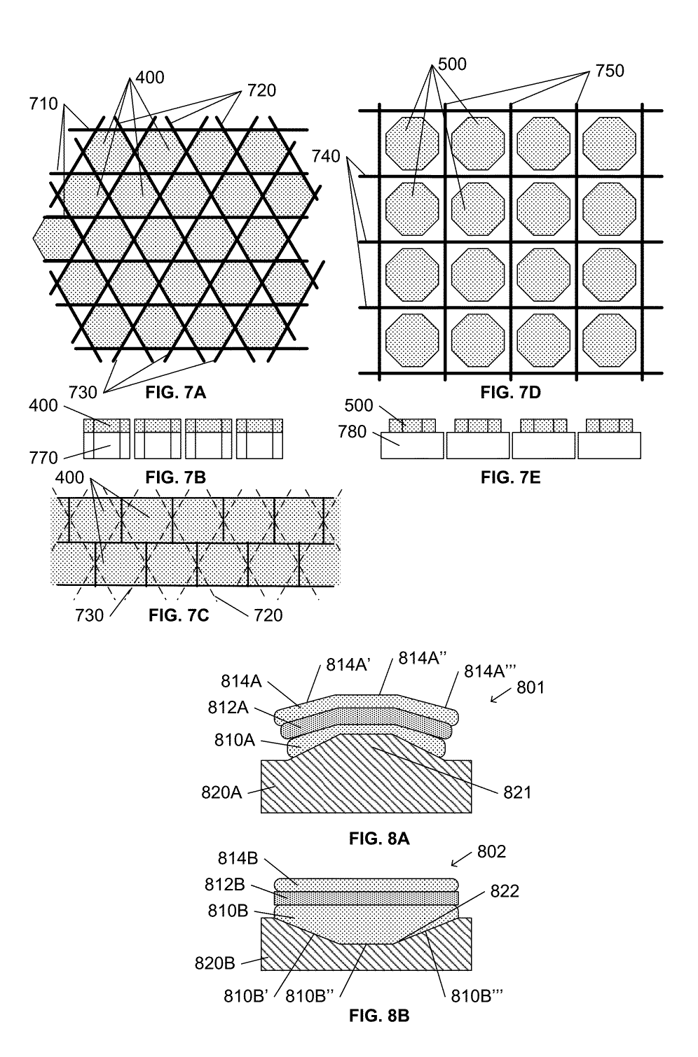

FIG. 7A illustrates an example wafer comprising a plurality of hexagonal light emitting elements 400. The bolder lines 710, 720, 730 illustrate cuts that may be made through the wafer to singulate the individual hexagonal light emitting elements 400, as illustrated in FIG. 7B, which illustrates a side view of the singulated light emitting elements 400 on a substrate 770. As illustrated, the resultant die, comprising the substrate 770 and the light emitting element 400 will be hexagonal, and the residual waste is minimal. In the example of FIG. 7A, the light emitting elements 400 may be created as rectangular light emitting elements that are shape to be hexagonal by the slicing along lines 720 and 730, as illustrated in FIG. 7C.

Alternatively, if the light emitting elements are formed on the wafer as individual elements with a polygon perimeter, the wafer may be cut in the orthogonal manner to produce rectangular portions of the substrate upon which the non-rectangular light emitting elements are situated, as illustrated in FIGS. 7D and 7E.

FIG. 7D illustrates a top view of a wafer wherein individual octagonal light emitting elements 500 are formed. Such forming may be accomplished using conventional photolithographic or other techniques common in the art of semiconductor fabrication, with a removable material situated between the elements 500. Other forming techniques, such as DRIE (Deep Reactive-Ion Etching), FIB (Focused Ion Beam) etching, and ICP (Inductive Coupled Plasma) etching may also be used. After forming the individual elements, the wafer may be sliced along the lines 740, 750, to singulate the individual light emitting elements 500.

FIG. 7E illustrates a cross section of the individual light emitting elements 500 after such slicing and removal of the material between the elements 500, if any. As illustrated, the octagonal light emitting elements 500 are situated upon the wafer substrate 780, which is shaped as a rectangularly shaped die. Situating the light emitting element on a rectangular die may facilitate the use of conventional picking and placement techniques for subsequent processing of the die.

Other techniques for forming and singulating non-rectangular light emitting elements on conventional or unconventional substrates will be evident to one of skill in the art in view of this disclosure. For example, the light emitting elements on the wafer (growth substrate) of either FIG. 7A or 7C may be attached to another substrate in a flip-chip embodiment, and the growth substrate may be subsequently removed. In this example, the shape of the die will be determined by how the second substrate is sliced, regardless of the placement of the light emitting elements on the growth substrate.

Using the aforementioned paradigm of an ideal spherical emitter, one of skill in the art will recognize that the principles of this invention are not limited to shaping the perimeter of a light emitting element.

Light emitting devices may have a rectangular cross-section (or side-view profile), as well as a rectangular perimeter (or top-view profile). Accordingly, changing the shape of either of these rectangular profiles may enhance the light output efficiency from the surfaces outlined by these profiles. In particular, changing the side-view profile of the light emitting element by increasing the number of surfaces ‘above’ or ‘below’ the light emitting layer may enhance the light output efficiency for light escaping from these surfaces.

FIGS. 8A-8B illustrate example cross sections of non-planar light emitting elements 801, 802. In these examples, each of the light emitting elements 801, 802 are formed upon features 821, 822 that are formed on or in the substrates 820A, 820B. Each of the light emitting elements 801, 802 includes an active layer 812A, 812B sandwiched between N-type and P-type semiconductor layers 810A, 810B and 814A, 814B. Because of the features 821, 822, the layers 810A, 810B, 812A, 812B and 814A, 814B of the light emitting elements 801-804 are non-planar.

In FIG. 8A, the light emitting elements 801 is convex, with the center region extending above the outer regions. The non-planar shape of the light emitting element will enhance the light extraction efficiency for light exiting the upper layer 814A by reducing the likelihood of total internal reflection at the outer surface of layer 814A.

In FIG. 8B, the light emitting element 802 is concave, with the center region extending below the outer regions. This configuration may be used in a ‘flip-chip’ embodiment, wherein light is intended to be emitted through the lower layer 810 after the substrate 820B is removed. The non-planar shape of the light emitting element 802 will enhance the light extraction efficiency for light exiting the lower layer 810B by reducing the likelihood of total internal reflection at the outer surface of layer 810B.

One of skill in the art will recognize that the particular shapes of the layers that are illustrated in these figures are merely presented for illustrative purposes, and other shapes may be formed as technology permits. One of skill in the art will also recognize that a combination of cross-section shaping and perimeter shaping may be used to increase the amount of light that directly escapes the surfaces of the light emitting element including the creation of facets on the concave or convex surfaces of substrates that are similar to 820A and 820B.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A light emitting element comprising:
an N-type layer,
a P-type layer,
an active layer that is situated between the N-type and P-type layers,
wherein:
the light emitting element includes a cross-section-view profile that includes a polygon with more than four sides, forming a light extraction region that includes a plurality of planar light extraction surfaces, at least one light extraction surface being non-orthogonal to, and non-planar with, an adjacent light extraction surface.

2. The light emitting element of claim 1, wherein a top profile of the light emitting element also includes another polygon with more than four sides.

3. (canceled)

4. The light emitting element of claim 1, including a substrate that includes a rectangular surface upon which the N-type, P-type, and active layers are situated.

5. The light emitting element of claim 2, wherein the polygon is a regular polygon.

6. The light emitting element of claim 1, wherein light emitting element is a polyhedron of at least seven sides.

7. The light emitting element of claim 1, wherein the light emitting element includes one or more reflective surfaces.

8. The light emitting element of claim 1, wherein the light emitting element has a shape that corresponds to a combination of multiple polygons or polyhedrons.

9. A substrate comprising:
a plurality of light emitting elements, each light emitting element having a cross-section-view profile that includes a polygon with more than four sides, forming a light extraction region that includes a plurality of planar light extraction surfaces, at least one light extraction surface being non-orthogonal to, and non-planar with, an adjacent light extraction surface.

10. The substrate of claim 9, wherein a top-view profile of the light emitting element also includes another polygon with more than four sides.

11. The substrate of claim 9, wherein the substrate includes features that cause the cross-section-view profile to be the polygon with more than four sides.

12. A method comprising:
forming a plurality of light emitting elements on a substrate, each light emitting element having a cross-section-view profile that includes a polygon with more than four sides, with a light extraction region that includes a plurality of planar light extraction surfaces, at least one light extraction surface being non-orthogonal to, and non-planar with, an adjacent light extraction surface.

13. The method of claim 12, wherein each light emitting element comprises a polyhedron of at least seven faces.

14. The method of claim 12, wherein at least one surface of each light emitting element is reflective.

15. The method of claim 12 including slicing the substrate to singulate the light emitting elements.

16. The method of claim 15, wherein the slicing is performed in two orthogonal directions to provide the singulated light emitting elements on a portion of the substrate that is rectangular.

17. The method of claim 15, wherein the slicing is performed in at least two non-orthogonal directions to provide the singulated light emitting elements on a portion of the substrate that is not rectangular.

18. The method of claim 12, including slicing the substrate using a plurality of straight line cuts to singulate the light emitting elements into light emitting devices having a plurality of planar light emitting surfaces.

19. The method of claim 12, wherein forming the light emitting elements includes forming an N-type layer and a P-type layer that sandwich an active layer, and one of the N-type layer and P-type layer provides the light extraction region.

20. The substrate of claim 9, wherein each light emitting element includes an N-type layer and a P-type layer that sandwich an active layer, and one of the N-type layer and P-type layer provides the light extraction region.
